(19) United States
(12) Patent Application Publication
(10) Pub. No.: US 2013/0076834 A1
(43) Pub. Date: Mar. 28, 2013

(54) INKJET HEAD AND METHOD FOR PRODUCING THE SAME

(71) Applicants: Norihito NOSAKA, Kanagawa (JP); Akira WAKABAYASHI, Kanagawa (JP); Shinya OGIKUBO, Kanagawa (JP); Minako HARA, Kanagawa (JP)

(72) Inventors: Norihito NOSAKA, Kanagawa (JP); Akira WAKABAYASHI, Kanagawa (JP); Shinya OGIKUBO, Kanagawa (JP); Minako HARA, Kanagawa (JP)

(73) Assignee: FUJIFILM CORPORATION, Tokyo (JP)

(21) Appl. No.: 13/601,935

(22) Filed: Aug. 31, 2012

(30) Foreign Application Priority Data
Sep. 22, 2011 (JP) 2011-206748

(51) Int. Cl. B41J 2/14; H01L 21/02

(52) U.S. Cl. 347/50; 438/21; 257/E21.002

(57) ABSTRACT

A flexible wiring circuit board has a second terminal section bonded and electrically connected to a first terminal section of a wiring circuit board of a discharge die. A drive signal is inputted to the first terminal section through the second terminal section, and then sent to a driver IC. The driver IC drives a piezoelectric element in accordance with the drive signal through a printed wiring pattern. Thereby, ink is discharged from an ink discharge opening. A copper ion diffusion inhibiting film is formed on a surface of a copper wiring member of the second terminal section on contact with a process liquid containing at least one of 1, 2, 3 triazole and 1, 2, 4 triazole. This inhibits diffusion of copper ions and copper ion migration resulting therefrom. Thus, malfunction due to the copper ion migration is inhibited.

### BACKGROUND OF THE INVENTION

1. Field of the Invention

The present invention relates to an inkjet head and a method for producing the same.

2. Description Related to the Prior Art

Recently, development of inkjet printers has been promoted to achieve high performance. Some models of the inkjet printers are required to have high output resolution of, for example, 1200 dpi comparable to that of offset printing. To achieve the high resolution, discharge openings and actuators such as piezoelectric elements, which allow ink to be discharged, need to be implemented with high density. For example, in U.S. Pat. No. 7,052,117, a semiconductor processing technique is employed to produce a discharge die having nozzles, ink channels, pump chambers, the piezoelectric elements, and the like. Thereby, the discharge openings are implemented with high density.

The ink channels are formed in the discharge die. Each ink channel has the pump chamber and the discharge opening. The discharge openings are provided on a bottom face of the discharge die. On a top face of the discharge die, the actuators, wiring circuit patterns, and integrated circuits are provided. The actuator, for example, the piezoelectric element, is provided in a position corresponding to the pump chamber. The wiring circuit pattern and the integrated circuit activate the actuator. The integrated circuit generates a drive signal for the actuator. When the discharge openings are implemented with high density, the wiring circuit patterns, each sending the drive signal to the corresponding actuator, are also formed with high density.

A terminal section of a wiring circuit board of the discharge die and a terminal section of a flexible wiring circuit board are put together and bonded using a bonding material such as solder or an anisotropic conductive adhesive. Thus, an electrical connection portion is formed. For example, the flexible wiring circuit board is provided with an insulating layer (substrate sheet) made from polyimide (PI) and copper wiring members formed on the insulating layer. Through an adhesive layer, a protective layer made from the PI is adhered to the copper wiring members except for the terminal section. Through the flexible wiring circuit board, the drive signal is inputted to the wiring circuit pattern of the die so as to activate the actuators independently. Thus, the ink is discharged.

Due to the structure of the inkjet head, fluids such as water, ink, and a solvent for removing the ink pass in the proximity of the electrical connection portion. When the fluid penetrates or permeates the connection portion of the flexible wiring circuit board, ion migration occurs between the wirings during the operation, which may cause short-circuit between the wirings. In particular, the ion migration is likely to occur when the wirings are arranged at a small pitch, for example, less than 100 μm. To inhibit the ion migration, high insulation performance is required.

In the flexible wiring circuit board, the thickness of the protective layer and the adhesive is in the order of less than 50 μm to have good flexibility. Because the wirings on the flexible wiring circuit board are protected only by extremely thin resin, the ion migration caused by moisture absorption occurs in long term use.

The ion migration refers to movements of metal ions through moisture caused by application of an electric field (electric potential difference) between electrodes. The moisture serves as a medium for migration of the metal ions. The ion migration causes the short-circuit in a portion different from the original electrical circuit. This short-circuit, being unexpected conduction, causes malfunction of a product, or at the worst, failure of the product.

Particularly in the inkjet head, the copper wiring member is protected only by the adhesive at an edge of the protective layer of the flexible wiring circuit board. Due to this structural feature, ion migration resistance is weakest at the edge, which is likely to cause the ion migration at the time of activation, resulting in the short-circuit. The short-circuit leads to incorrect image rendering and results in a printing defect such as deterioration of image quality or failure. Thus, the ion migration resistance needs to be improved.

To inhibit the ion migration in the flexible wiring circuit board of the inkjet head, generally, a sealant is used to inhibit penetration of the fluid. The sealant has various requirements. For example, the sealant needs to be highly moisture resistant so as to inhibit moisture penetration in the sealant with time. The sealant needs to be flexible, because stress is often applied to the sealant due to the structural causes. Furthermore, the sealant needs to have solvent resistance, because the solvent is used to remove the ink from the inkjet head. Selection or development of the sealant satisfying all the above requirements takes a long time. In a long term, the sealant is degraded by the solvent, resulting in degradation of the moisture resistance. The sealant alone cannot inhibit the ion migration. Accordingly, the flexible wiring circuit board itself needs the ion migration resistance. For example, in Japanese Patent Laid-Open Publication No. 2008-126629, a protective film containing an inorganic material such as gold is affixed to the protective layer of the flexible wiring circuit board to inhibit moisture penetration to the flexible wiring circuit board. Thereby, the ion migration between the wirings on the flexible wiring circuit board is inhibited.

In Japanese Patent Laid-Open Publication No. 9-064493, a conductive layer is formed to cover the copper wiring member so as not to diffuse copper into a base and adhesive surrounding the copper wiring member. Thereby, corrosion of the copper wiring member caused by moisture penetration in a resin material is inhibited. Thus, the ion migration is inhibited.

As for the Japanese Patent Laid-Open Publication No. 2008-126629, it is difficult to precisely affix the protective film made from the inorganic material to the protective layer. Accordingly, an area at an edge of the protective layer is often left uncovered. A liquid permeates from the uncovered area, which degrades the ion migration resistance. However, when the edge of the protective layer is completely covered with the protective film, the protective film may interfere with the wiring circuit board of the die due to the structure. This obstructs the connection of the electrical connection portion.

In the Japanese Patent Laid-Open Publication No. 9-064493, extra steps, for example, a re-exposure and development step for forming a gap in the order of several μm between the copper wiring member and a mask layer and a step for forming a conductive film made from nickel on the gap, are necessary in forming the copper wiring member. Accordingly, the production steps are complicated and burdensome and increase cost.

### SUMMARY OF THE INVENTION

An object of the present invention is to provide an inkjet head having high resistance to moisture and a solvent so as to inhibit ion migration and a method for producing the same.

An inkjet head of the present invention includes a wiring circuit board and a flexible wiring circuit board. The wiring circuit board includes an opening for supplying ink, an element for allowing the ink to be discharged, a wiring circuit for driving the element, and a first terminal section for inputting a drive signal for driving the element to the wiring circuit. The flexible wiring circuit board includes a second terminal section bonded and electrically connected to the first terminal section.

The second terminal section inputs the drive signal to the first terminal section. The second terminal section has a first wiring member containing copper and a copper ion diffusion inhibiting film. The copper ion diffusion inhibiting film covers at least a part of the first wiring member and contains at least one of 1,2,3 triazole and 1,2,4 triazole.

It is preferable that the inkjet head further includes a sealing section using resin. The resin is filled to cover a bonded portion of the first terminal section and the second terminal section from outside of the bonded portion.

It is preferable that the first terminal section has a second wiring member containing the copper, and at least a part of the second wiring member is covered with the copper ion diffusion inhibiting film.

It is preferable that at least one of the wiring circuit board and the flexible wiring circuit board has a third wiring member containing the copper, and at least a part of the third wiring member is covered with the copper ion diffusion inhibiting film.

It is preferable that at least one of the first, second, and third wiring members is made of copper-alloy.

It is preferable that at least one of the wiring circuit board and the flexible wiring circuit board has a wiring member containing the copper, and at least a part of the wiring member is covered with the copper ion diffusion inhibiting film.

It is preferable that at least one of the first wiring member and the wiring member is made of copper-alloy.

It is preferable that apart of the first wiring is covered with a plating film not containing the copper.

A method for producing the inkjet head includes a coating forming step, a film forming step, a bonding step, and a sealing step. In the coating forming step, a flexible wiring circuit board is contacted with a process liquid to form a process liquid coating on the flexible wiring circuit board. The flexible wiring circuit board includes a second terminal section having a wiring member containing copper. The process liquid contains at least one of 1, 2, 3 triazole and 1, 2, 4 triazole. In a film forming step, the process liquid coating is washed away with a solvent to remove the process liquid coating except for the process liquid coating on a surface of the wiring member so as to form a copper ion diffusion inhibiting film on the surface of the wiring member. In the bonding step, the second terminal section formed with the copper ion diffusion inhibiting film is bonded and electrically connected to the first terminal section. In the sealing step, resin is filled to cover a bonded portion of the first and second terminal sections from outside of the bonded portion.

It is preferable that the method further includes a plating step. In the plating step, metal plating not containing the copper is formed on the wiring member before contacting the flexible wiring circuit board with the process liquid.

According to the present invention, the wiring member containing copper of the second terminal section of the flexible wiring circuit board is provided with a copper ion diffusion inhibiting film containing at least one of 1,2,3 triazole and 1,2,4 triazole. Thereby, the copper ion diffusion inhibiting film provides the ion migration resistance to the flexible wiring circuit board in a simple configuration. Thus, the inkjet head excellent in ion migration resistance is produced without increase in cost.

### BRIEF DESCRIPTION OF THE DRAWINGS

The above and other objects and advantages of the present invention will be more apparent from the following detailed description of the preferred embodiments when read in connection with the accompanied drawings, wherein like reference numerals designate like or corresponding parts throughout the several views, and wherein:

FIG. 1 is a perspective view of an inkjet head;

FIG. 2 is an exploded perspective view of the inkjet head;

FIG. 3 is a perspective view of a discharge die;

FIG. 4 is a partial cross-sectional view showing the discharge die and a head body;

FIG. 5 is an exploded perspective view showing a connection between the discharge die and a flexible wiring circuit board;

FIG. 6 is a perspective cross-sectional view of the inkjet head;

FIG. 7 is a flowchart showing steps of a method for producing the inkjet head of the present invention;

FIG. 8A is a bottom view of the flexible wiring circuit board;

FIG. 8B is a cross-sectional view showing bonding between the flexible wiring circuit board and the discharge die;

FIG. 8C is a plan view of a wiring circuit board of the discharge die;

FIG. 9 is a perspective view showing an electrical connection portion of the flexible wiring circuit board;

FIG. 10 is a cross-sectional view of the flexible wiring circuit board cut along a line X-X in FIG. 9;

FIG. 11 is a cross-sectional view of the flexible wiring circuit board, cut along the line X-X in FIG. 9, on which a process liquid coating is formed on an insulating layer after a liquid contacting substep;

FIG. 12 is a cross-sectional view of the flexible wiring circuit board, cut along the line X-X in FIG. 9, with copper wiring members each covered with a copper ion diffusion inhibiting film formed after a cleaning step and a drying step;

FIG. 13 is a cross-sectional view of the flexible wiring circuit board of another embodiment, cut along the line X-X in FIG. 9, with the copper wiring members each provided with a plating film;

FIG. 14 is a cross-sectional view of the flexible wiring circuit board, cut along the line X-X in FIG. 9, on which a process liquid coating is formed on an insulating layer after the cleaning step and the drying step; and

FIG. 15 is a cross-sectional view of the flexible wiring circuit board, cut along the line X-X in FIG. 9, with copper wiring members each covered with the plating film and the copper ion diffusion inhibiting film after the cleaning step and the drying step.

### DESCRIPTION OF THE PREFERRED EMBODIMENTS

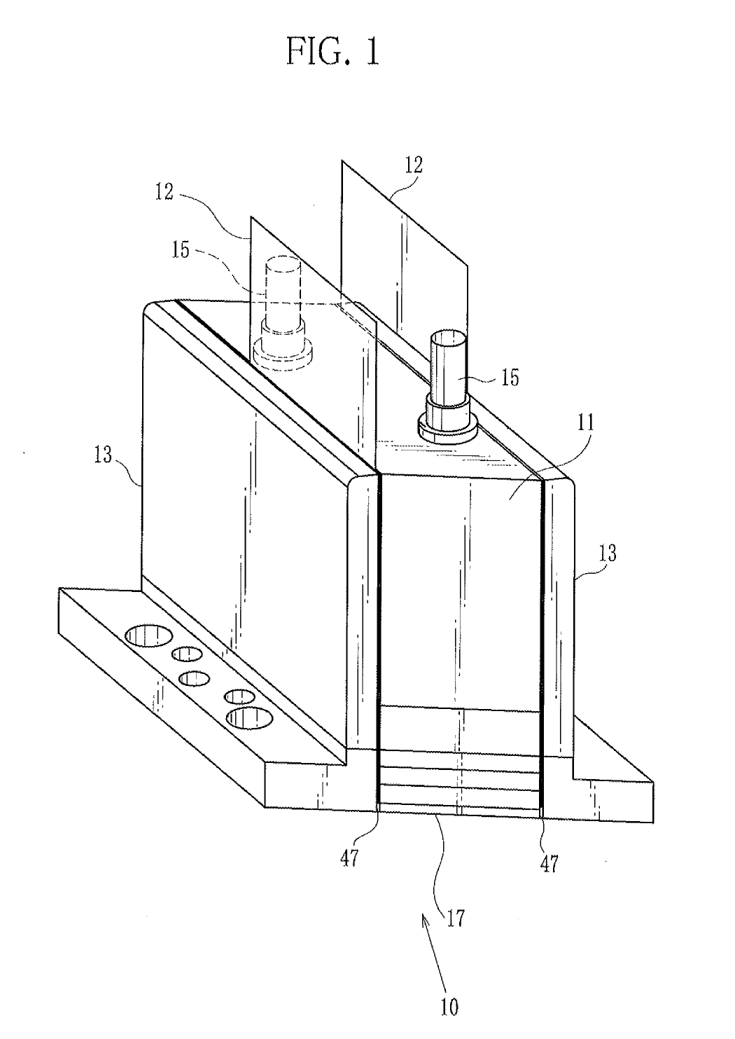

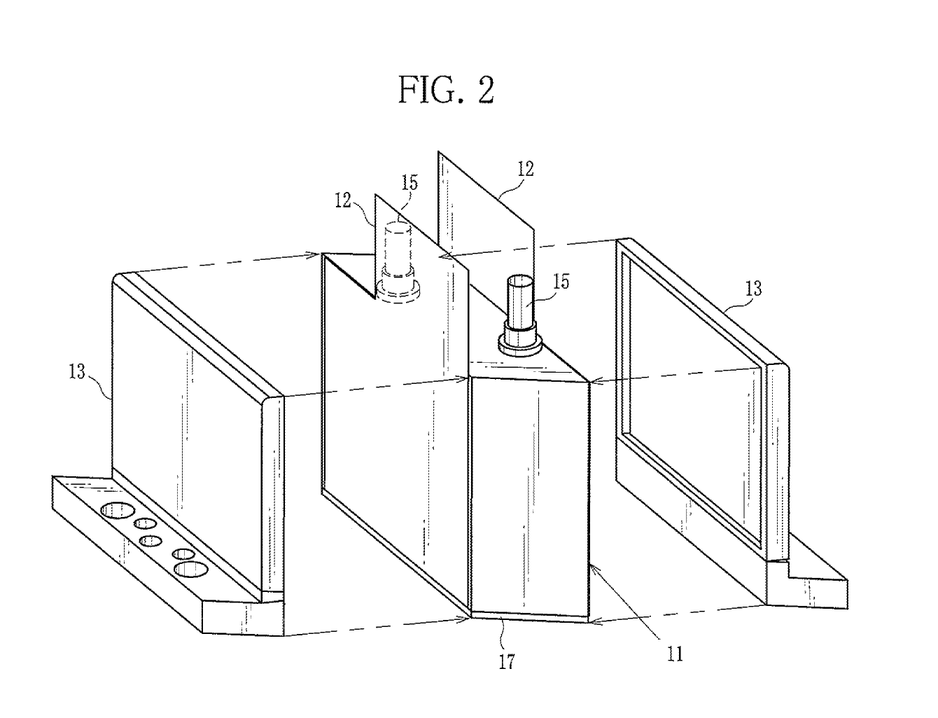

In FIG. 1, an inkjet head 10 is composed of a head body 11, a pair of flexible wiring circuit boards 12, and a pair of mounting frames 13. In FIG. 2, the head body 11 has a rectangular parallel-piped shape. Two tube connection nozzles 15 are provided on a top face of the head body 11. A discharge die 17 is provided on a bottom face of the head body 11. One of the tube connection nozzles 15 is for supplying ink and the other is for recovering the ink. When the inkjet head 10 is installed in an inkjet printer (not shown), an ink tube from an ink supply tank (not shown) is connected to the tube connection nozzle 15 for supplying the ink and an ink tube from an ink recovery tank (not shown) is connected to the tube connection nozzle 15 for recovering the ink.

On each side of the head body 11, the flexible wiring circuit board 12 is attached. To protect the flexible wiring circuit boards 12, the mounting frame 13 is adhered to each flexible wiring circuit board 12 using a two-liquid type adhesive, for example.

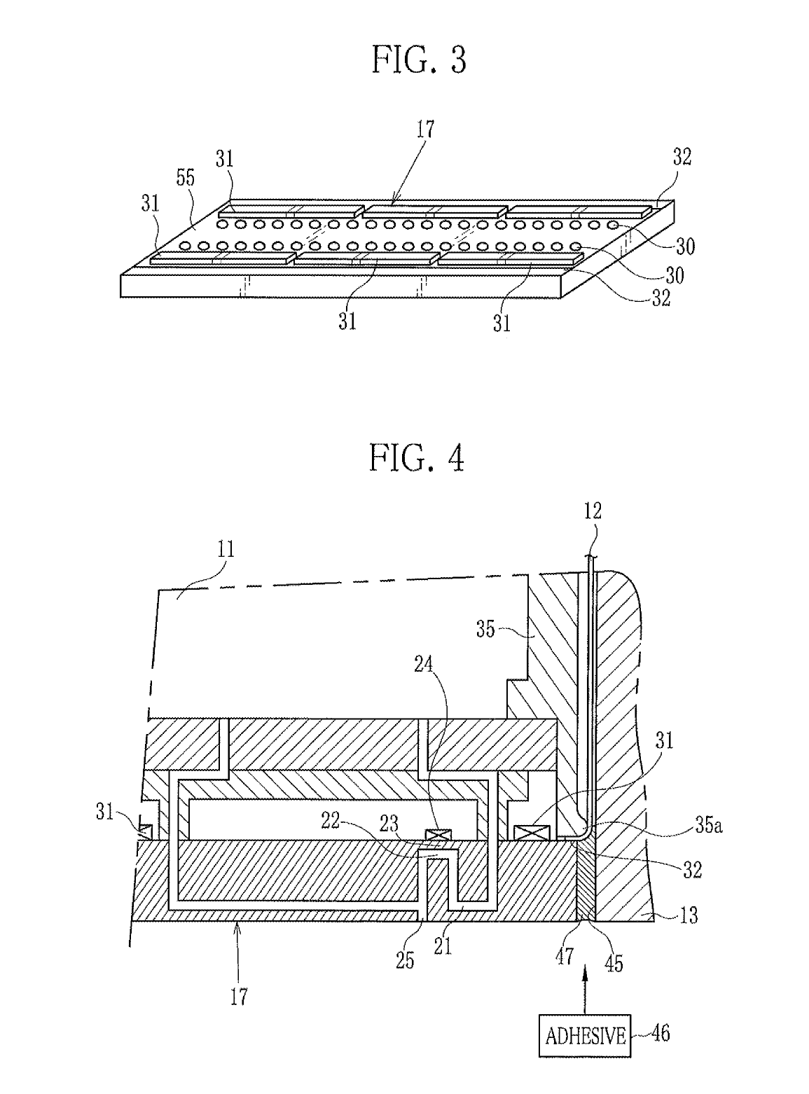

As shown in FIG. 3, the discharge die 17 is formed with parallelogram or rectangular plate members. As shown in FIG. 4, an ink channel 21 is routed through the discharge die 17. Apart of the ink channel 21 forms a pump chamber 22. A piezoelectric element 24 is disposed above the pump chamber 22 through a thin film 23. The piezoelectric element 24 deforms the thin film 23 to change a capacity of the pump chamber 22. Thereby, an ink droplet is discharged from an ink discharge opening 25.

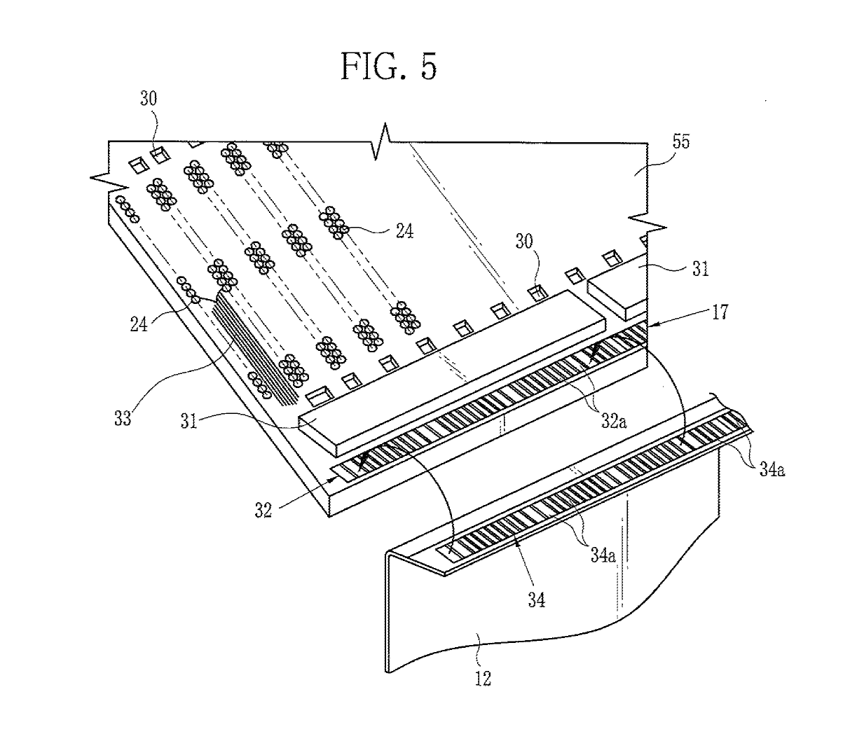

As shown in FIG. 5, on a top face of the discharge die 17, a wiring circuit board 55 is formed. The wiring circuit board 55 is provided with ink passage openings 30, driver ICs 31, a first terminal section 32 to be connected to the flexible wiring circuit board 12, in addition to the piezoelectric elements 24. The piezoelectric elements 24 are connected to the driver IC 31 through a printed wiring pattern 33. The driver IC 31 is connected to the first terminal section 32. A second terminal section 34 provided on the flexible wiring circuit board 12 is electrically connected to the first terminal section 32.

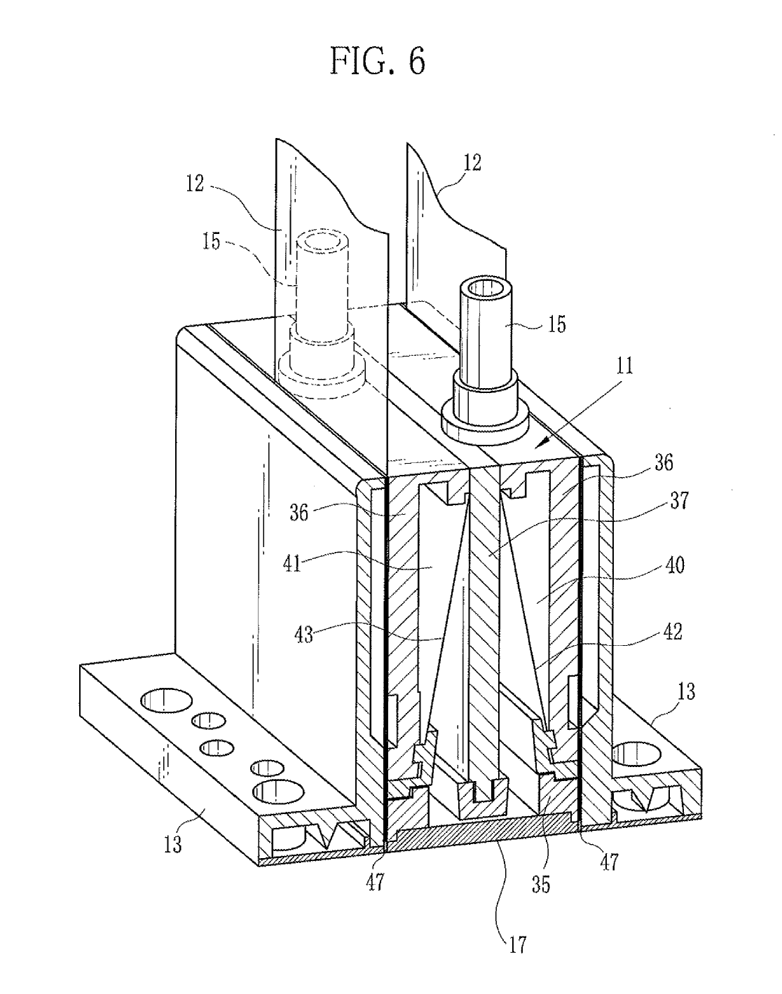

As shown in FIG. 6, after the flexible wiring circuit board 12 is attached to the head body 11, a support 35, a housing 36, a partition plate 37, and the like are disposed over a top face of the discharge die 17 and adhered using an adhesive. Thus, the head body 11 is formed.

The head body 11 is formed by disposing the housing 36 on each side of the partition plate 37. With the use of the partition plate 37, an ink inlet chamber 40 and an ink outlet chamber 41 are formed inside the head body 11. Stainless filters 42 and 43 are disposed in diagonal directions in the chambers 40 and 41, respectively.

As shown in FIG. 4, each flexible wiring circuit board 12 is bent at 90° along a curved portion 35a of the support 35 while being in tightly contact with the curved portion 35a so as to be disposed along a side wall of the head body 11. Note that the FIG. 4 is elongated in its height direction to illustrate the minute parts such as the piezoelectric element 24 and the driver IC 31. Accordingly, FIG. 4 does not dimensionally coincide with FIG. 6 that is a cross-sectional view of the whole inkjet head 10.

Next, as shown in FIG. 2, the head body 11 is sandwiched by the mounting frames 13. The mounting frames 13 are adhered to the head body 11 using the two-liquid mixture type adhesive. Thereby, the head body 11 (with the flexible wiring circuit boards 12) and the mounting frames 13 are adhered and integrated.

As shown in FIG. 4, a sealant adhesive (resin) 46 is filled in a gap 45 between the discharge die 17 and the mounting frame 13 of the integrated head body 11 to form a sealing section 47. The sealant adhesive 46 is filled to cover a bonded portion of the first and second terminal sections 32 and 34 from outside of the bonded portion. The adhesive 46 is a two-liquid type composed of a main agent and a plasticizer (hardener). Progress of polymerization in the two-liquid type adhesive 46 depends on temperature. Examples of the adhesive 46 include an epoxy adhesive, an urethane adhesive, a silicon adhesive, and a fluorine gel adhesive. In this embodiment, the fluorine jel adhesive 46 (SIFEL, available from Shin-Etsu Chemical Co., Ltd.) is used. The SIFEL is excellent in chemical resistance and durability.

The flexible wiring circuit board 12 is connected to a control circuit (not shown). A drive signal from the control circuit is inputted from the second terminal section 34 of the flexible wiring circuit board 12 to the first terminal section 32 of the wiring circuit board 55. Then, the drive signal is sent to the driver IC 31. Based on the drive signal, the driver IC 31 generates a drive signal for the piezoelectric element 24 to activate each piezoelectric element 24 independently through the printed wiring pattern 33. In response to the drive signal, a droplet is discharged from each ink discharge opening 25. The ink droplets are discharged in a main scan direction on a recording material (not shown). The recording material is moved in a sub-scanning direction orthogonal to the main scan direction each time the ink droplets are discharged. Thus, an image is recorded on the recording material.

On the bottom face of the discharge die 17, the ink discharge openings 25 are arranged in a staggered matrix in rows in the main scan direction and columns in a direction oblique to the main scan direction. This enables high density implementation of the ink discharge openings 25. An image is recorded with output resolution of, for example, 1200 dpi using the rows and/or columns of the ink discharge openings 25.

As shown in FIG. 5, before the assembly of the head body 11 (see FIG. 4), a second terminal section 34 of the flexible wiring circuit board 12 is overlaid onto the first terminal section 32 of the discharge die 17 and soldered by heat-pressing.

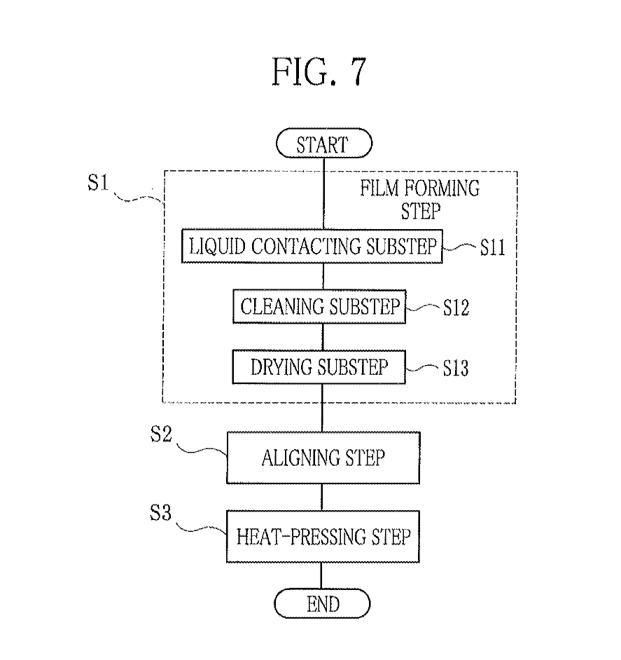

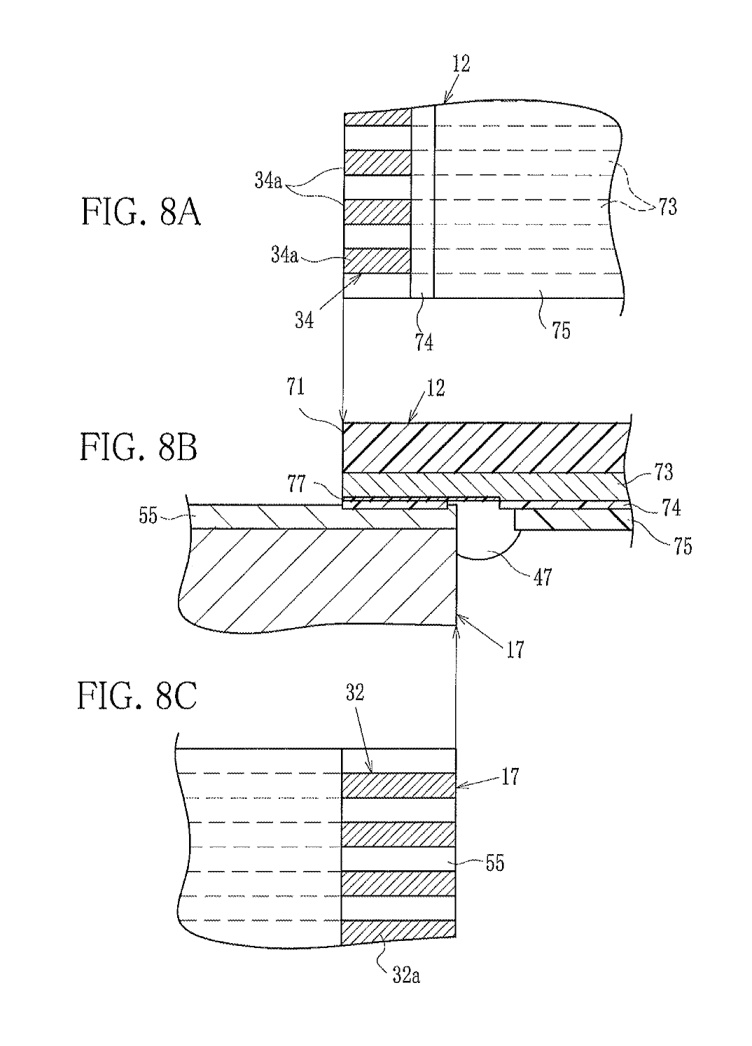

As shown in FIG. 7, to bond the flexible wiring circuit board 12 to the wiring circuit board 55 provided on the discharge die 17, a film forming step S1, an aligning step S2, and a heat-pressing step S3 are carried out in this order. In the film forming step S1, a copper ion diffusion inhibiting film 77 is formed on the flexible wiring circuit board 12. In the aligning step S2, the flexible wiring circuit board 12 and the wiring circuit board 55 are aligned to each other. Then in the heat-pressing step S3, the flexible wiring circuit board 12 and the wiring circuit board 55 aligned are heat-pressed together. Thus, the flexible wiring circuit board 12 and the wiring circuit board 55 are bonded to each other. As shown in FIG. 8B, the first terminal section 32 and the second terminal section 34 are heat-pressed and soldered to each other through the steps S1 to S3. Then, the sealant adhesive 46 is filled to cover the bonded portion of the first and second terminal sections 32 and 34 from outside of the bonded portion. Thereby, the sealing section 47 is formed.

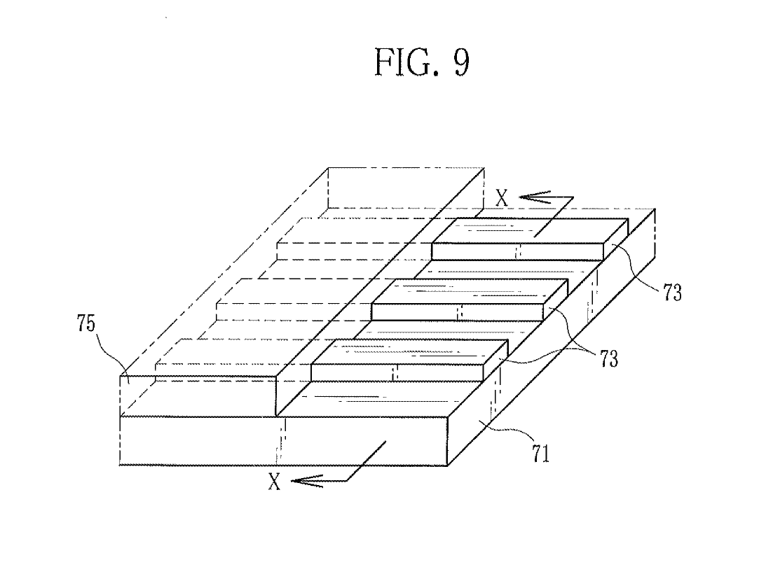

As shown in FIGS. 8A, 8B, 8C, and 9, the flexible wiring circuit board 12 is provided with an insulating layer 71 made from PI (polyimide) and copper wiring members 73 formed on the insulating layer 71. A protective layer 75 made from the PI is adhered to the flexible wiring circuit board 12, except for the first terminal section 32, through an adhesive layer 74. Note that the copper wiring member 73 may be made from a copper alloy instead of copper. The insulating layer 71 has the thickness of 25 μm, for example. Each copper wiring member 73 has the thickness of 12 μm, for example. The adhesive layer 74 has the thickness of 17.5 μm, for example. The protective layer 75 has the thickness of 12.5 μm, for example. A plated layer (not shown) such as a solder plated layer or gold/tin plated layer is formed on the surface of each of the first and second terminal sections 32 and 34 so as to facilitate the bonding between them. The plated layers are melted by the heat-pressing and bonded and integrated to the first and second terminal sections 32 and 34.

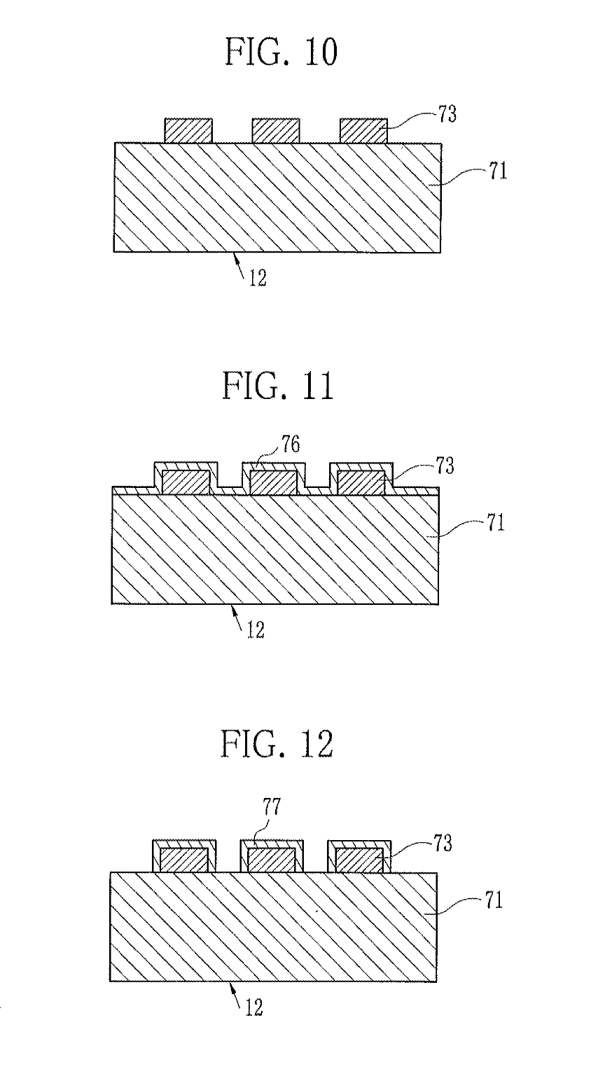

As shown in FIGS. 10 to 12, in the film forming step S1, the copper ion diffusion inhibiting film 77 is formed on each copper wiring member 73 of the flexible wiring circuit board 12. As shown in FIG. 8B, the flexible wiring circuit board 12 is provided with the insulating layer 71, being a substrate body, the copper wiring members 73 disposed on the insulating layer 71, the protective layer 75 for covering the copper wiring member 73 (leaving a part of each copper wiring member 73 uncovered or exposed), the adhesive layer 74 for adhering the protective layer 75, and the cupper ion diffusion inhibiting film 77 for covering each of the exposed cupper wiring members 73.

As shown in FIG. 7, the film forming step S1 is composed of a liquid contacting substep S11, a cleaning substep S12, and a drying substep S13. In the liquid contacting substep S11, the process liquid is, for example, applied to contact the flexible wiring circuit board's surface formed with the copper wiring members 73. In the cleaning substep S12 after the application of the process liquid, the surplus process liquid on the flexible wiring circuit board 12 is removed by cleaning. In the drying substep S13, a cleaning fluid remaining on the flexible wiring circuit board 12 is dried.

The process liquid used in the liquid contacting substep S11 contains at least one of 1,2,3-triazole and 1,2,4-triazole (hereinafter, may referred to as the azole compound, being the general term for the 1,2,3-triazole and the 1,2,4-triazole). Note that the process liquid may be a mixture of the 1,2,3-triazole and the 1,2,4-triazole. In the present invention, a desired effect is obtained by the use of the azole compound. On the other hand, the desired effect is not obtained when, for example, aminotriazole is used instead of the azole compound.

A total content of the azole compound in the process liquid is not particularly limited. The total content of the azole compound relative to the total amount of the process liquid is preferably at least 0.01 mass % and at most 10 mass %, more preferably at least 0.1 mass % and at most 5 mass %, and especially preferably at least 0.25 mass % and at most 5 mass % in view of easiness in forming the copper ion diffusion inhibiting film 77 and controlling a deposition amount of the copper ion diffusion inhibiting film 77. When the total content of the azole compound is too high, it is difficult to control the deposition amount of the copper ion diffusion inhibiting film 77. When the total content of the azole compound is too low, a deposition rate of the copper ion diffusion inhibiting film 77 is reduced, resulting in low productivity.

The process liquid used in the liquid contacting substep S11 may include a solvent. The solvent is not particularly limited. Examples of the solvent include water, an alcohol-based solvent (for example, methanol, ethanol, or isopropanol), a ketone-based solvent (for example, acetone, methylethyl ketone, or cyclohexanone), an amide-based solvent (for example, formamide, dimethylacetamide, or N-methylpyrrolidone), a nitrile-based solvent (for example, acetonitrile or propionitrile), an ester-based solvent (for example, methyl acetate or ethyl acetate), a carbonate-based solvent (for example, dimethyl carbonate or diethyl carbonate), an ether-based solvent, and a halogen-based solvent. A mixture of two or more types of solvents may be used. Of the above solvents, the water and the alcohol-based solvent are preferable in view of safety in producing the flexible wiring circuit board 12. The water is especially preferable as the solvent because the azole compound is easily deposited on the surface of the copper wiring member 73 specifically when an immersion method is employed to put the flexible wiring circuit board 12 in contact with the process liquid. A solvent content in the process liquid is not particularly limited, but preferably in the range of 90 mass % to 99.99 mass %, and more preferably in the range of 95 mass % to 99.99 mass %, and especially preferably in the range of 95 mass % to 99.75 mass %.

On the other hand, it is preferable that the process liquid does not substantially contain the copper ions so as to improve insulation reliability between the copper wiring members 73 of the flexible wiring circuit board 12. When the process liquid contains the copper ions exceeding a predetermined amount, the copper ions are transferred into the copper ion diffusion inhibiting film 77 during the formation of the copper ion diffusion inhibiting film 77. This reduces the effect of inhibiting the copper ion migration, which in result impairs the insulation reliability between the copper wiring members 73. Note that “the process liquid does not substantially contain the copper ions” means that the content of the copper ions in the process liquid is less than or equal to 1 μmol/L (liter). The content of the copper ions is more preferably less than or equal to 0.1 μmol/L, and most preferably 0 μmol/L.

To improve the insulation reliability between the copper wiring members 73 of the flexible wiring circuit board 12, it is preferable that the process liquid does not substantially contain an etching agent for the copper or the copper alloy. When the process liquid contains the etching agent, the copper (or copper-alloy) wiring member 73 is etched when the flexible wiring circuit board 12 comes in contact with the process liquid, which may cause elution of the copper ions into the process liquid. As a result, the copper ion diffusion inhibiting film 77 contains the copper ions. This reduces the effect of inhibiting the copper ion migration, which in result impairs the insulation reliability between the copper wiring members 73.

Examples of the etching agent include an organic acid (for example, sulfuric acid, nitric acid, hydrochloric acid, acetic acid, formic acid, or hydrofluoric acid), an oxidizer (for example, hydrogen peroxide or concentrated sulfuric acid), a chelating agent (for example, iminodiacetic acid, nitrilotriacetic acid, ethylene diamine tetra acetic acid, ethylene diamine, ethanolamine, or aminopropanol), and a thiol compound. The etching agent includes a compound capable of etching the copper, for example, imidazole or its derivative compound. Note that “the process liquid does not substantially contain the etching agent” means that the content of the etching agent relative to the total amount of the process liquid is less than or equal to 0.01 mass %. To improve the insulation reliability between the copper wiring members 73, the content of the etching agent is more preferably less than or equal to 0.001 mass %, and most preferably 0 mass %.

A pH of the process liquid is not particularly limited. It is preferable that the pH of the process liquid is in the range of 5 to 12 in view of forming the copper ion diffusion inhibiting film 77. The pH is more preferably in the range of 5 to 9, and furthermore preferably in the range of 6 to 8, to achieve excellent insulation reliability between the copper wiring members 73 of the flexible wiring circuit board 12. When the pH is less than 5, the elution of the copper ions from the copper wiring member 73 is promoted, which means that the copper ion diffusion inhibiting film 77 contains a high amount of the copper ions. As a result, the effect of inhibiting the copper ion migration is reduced. When the pH of the process liquid exceeds 12, copper hydroxide precipitates, facilitating oxidative dissolution. As a result, the effect of inhibiting the copper ion migration is reduced. Note that the pH is controlled using a known acid (for example, the hydrochloric acid or the sulfuric acid) or a known base (for example, sodium hydroxide). The pH is measured using a known measuring instrument, for example, a pH meter, when a water medium is used. The process liquid may contain other additives, for example, a pH controller, a surfactant, a preservative, and an anti-precipitation agent.

The solvent used in the cleaning substep S12 is not particularly limited. Any solvent may be used as long as it removes the surplus azole compound deposited on the surfaces other than the surfaces of the exposed copper wiring members 73. Examples of the solvent include, for example, the water, the alcohol-based solvent (for example, the methanol, the ethanol, or the propanol), the ketone-based solvent (for example, acetone, methyl ethyl ketone, or cyclohexanone), the amide-based solvent (for example, formamide, dimethylacetamide, or N-methylpyrrolidone), the nitrile-based solvent (for example, the acetonitrile or the propionitrile), the ester-based solvent (for example, the methyl acetate or the ethyl acetate), the carbonate-based solvent (for example, the dimethyl carbonate or the diethyl carbonate), the ether-based solvent, and the halogen-based solvent. A mixture of two or more types of solvents may be used. Particularly, in view of liquid immersion of the micro wirings, a solvent containing at least one selected from a group consisting of the water, the alcohol-based solvent, and the methyl ethyl ketone is preferable. A mixture of the alcohol-based solvent and the water is more preferable.

The boiling point (measured at 25° C., 1 atmospheric pressure) of the solvent is not particularly limited. In view of safety, the boiling point is preferably in the range of 75° C. to 100° C., and more preferably in the range of 80° C. to 100° C. The surface tension of the solvent (at 25° C.) is not particularly limited. The surface tension is preferably in the range of 10 mN/m to 80 mN/m, and more preferably in the range of 15 mN/m to 60 mN/m, in which washability and insulation reliability of the copper wiring members 73 improve.

In the liquid contacting substep S11, the flexible wiring circuit board 12 comes in contact with the process liquid. To be more specific, the flexible wiring circuit board 12 (see FIG. 10) having the copper wiring members 73 on the insulation layer 71 comes in contact with the process liquid. Thereby, a process liquid coating 76 containing the azole compound is formed on the surfaces of the copper wiring members 73 and the surfaces of the insulating layer 71 between the copper wiring members 73 (see FIG. 11). The process liquid coating 76 contains the azole compound. A content of the azole compound in the process liquid coating 76 is equivalent to the content of the azole compound in the copper ion diffusion inhibiting film 77. The amount of the deposition is not particularly limited, but preferred to be enough to form the copper ion diffusion inhibiting film 77 of the desired amount even after the cleaning step S12 is performed. The method for contacting the insulating layer 71 with the process liquid is not particularly limited. Any known method may be employed, for example, dipping, showering, spraying, or spin-coating. The dipping, the showering, and the spraying are preferable in view of easiness in processing and in controlling processing time. It is preferable to perform ultrasonic processing during the dipping to improve the immersion of micro regions in the process liquid. In view of controlling the amount of the deposition of the copper ion diffusion inhibiting film 77, the liquid temperature of the process liquid at the time of the contact with the flexible wiring circuit board 12 is preferably in the range of 5° C. to 60° C., and more preferably in the range of 15° C. to 30° C. In view of controlling the amount of the deposition of the copper ion diffusion inhibiting film 77 and productivity, the contact time is preferably in the range of 10 seconds to 30 minutes, and more preferably in the range of 15 seconds to 10 minutes, and furthermore preferably in the range of 30 seconds to 5 minutes.

In the cleaning substep S12, the flexible wiring circuit board 12 after the liquid contacting substep S11 is cleaned with the solvent (cleaning fluid or solvent) so as to remove the azole compound from the surfaces other than the surfaces of the exposed copper wiring members 73. Thereby, the copper ion diffusion inhibiting film 77 is formed only on the exposed surfaces (including the side walls) of the copper wiring members 73. To be more specific, as shown in FIGS. 11 and 12, the surplus azole compound (such as the process liquid coating 76) deposited on the surfaces between the copper wiring members 73 is removed by the cleaning. Thereby, the copper ion diffusion inhibiting film 77 is formed only on the exposed surface (including the side walls) of each copper wiring member 73. Note that in the cleaning substep S12, the process liquid coating 76 containing the azole compound, formed on the exposed surfaces of the insulating layer 71 between the copper wiring members 73, is removed as well as the coating (not shown) containing the azole compound, formed on the protective layer 75 in FIG. 9.

The cleaning methods are not particularly limited. Any known method may be employed. For example, a cleaning solvent may be applied to the flexible wiring circuit board 12 after the liquid contacting substep S11, or the flexible wiring circuit board 12 may be immersed in the cleaning solvent after the liquid contacting substep S11. To improve the immersion of the micro regions in the cleaning fluid, it is preferable to perform the ultrasonic processing during the dipping. In particular, when the copper wiring member 73 exposed is supported by the insulating layer 71, the cleaning by dipping, showering, or spraying is preferable. When a part of the copper wiring member 73 exposed is not supported by the insulating layer 71, the cleaning by the dipping is preferable in view of water pressure resistance of the copper wiring member 73. In view of controlling the amount of the deposition of the copper ion diffusion inhibiting film 77, the liquid temperature of the cleaning solvent is preferably in the range of 5° C. to 60° C., and more preferably in the range of 15° C. to 30° C. The contact time between the flexible wiring circuit board 12 and the cleaning solvent is preferably in the range of 10 seconds to 10 minutes, and more preferably in the range of 15 seconds to 5 minutes in view of productivity and controlling the amount of the deposition of the copper ion diffusion inhibiting film 77.

As shown in FIG. 12, the copper ion diffusion inhibiting film 77 containing the azole compound is formed on the surface (including the side walls) of each of the exposed copper wiring members 73 through the substeps S11 to S13. It is preferable that the process liquid coating 76 containing the azole compound is substantially removed from the surfaces other than the surfaces of the exposed copper wiring members 73. In other words, it is preferable that the copper ion diffusion inhibiting film 77 is formed only on the surfaces of the substantially exposed copper wiring members 73. Note that the surface of the copper wiring member 73 includes the top face and the side walls of the copper wiring member 73, but does not include the bottom face contacting the insulating layer 71 of the flexible wiring circuit board 12.

In the present invention, the copper ion diffusion inhibiting film 77 having the deposition amount enough to inhibit the copper ion migration is obtained even after the cleaning using the solvent. Note that the process liquid coating 76 containing the azole compound forms a complex with the copper. Thereby, the process liquid coating 76 forms the copper ion diffusion inhibiting film 77. The process liquid coating 76 on the insulating layer 71 of the flexible wiring circuit board 12 or the like is washed away using the solvent. Thereby, the copper ion diffusion inhibiting film 77 is formed only on each surface containing the copper. For example, when benzotriazole is used instead, the solvent washes away most of the benzotriazole. Thus, the desired effect is not achieved. When a process liquid contains the benzotriazole and the etching agent or the imidazole compound having the etching property, the organic film being formed contains the copper ions and therefore does not inhibit the copper ion diffusion. As a result, the desired effect is not achieved.

To further inhibit the copper ion migration, the content of the azole compound in the copper ion diffusion inhibiting film 77 is preferably in the range of 0.1 mass % to 100 mass %, more preferably in the range of 20 mass % to 100 mass %, and especially preferably in the range of 50 mass % to 100 mass %. Particularly, it is preferable that the copper ion diffusion inhibiting film 77 is made substantially from the azole compound. When the total content of the azole compound is too low, the effect of the copper ion diffusion inhibiting film 77 to inhibit the copper ion diffusion decreases.

It is preferable that the copper ion diffusion inhibiting film 77 does not substantially contain the copper ions. When the copper ions or metallic copper contained in the copper ion diffusion inhibiting film 77 exceeds a predetermined amount, the effect of the present invention may be reduced.

The deposition amount of the azole compound on the surfaces of the exposed copper wiring members 73 relative to the total surface area of the copper wiring members 73 is preferably greater than or equal to 5×10⁻⁹ g/mm², and more preferably greater than or equal to 1×10⁻⁸ g/mm². The effect of inhibiting the copper ion migration is superior in the above range. Note that the upper limit is not particularly limited. However, in view of production, the deposition amount is more preferably greater than or equal to 1×10⁻⁶ g/mm². Note that the deposition amount is measured using a known method, for example, an extinction method. To be more specific, first, the copper ion diffusion inhibiting film 77 between the copper wiring members 73 is washed away using the water (referred to as an extraction method using water). Then, the copper ion diffusion inhibiting films 77 on the copper wiring members 73 are extracted using the organic acid (for example, the sulfuric acid) and the absorptivity is measured. The deposition amount is calculated from the amount of the liquid and the area applied.

Note that it is preferable that the process liquid coating 76 containing the azole compound is substantially removed from the surface of the insulating layer 71 between the copper wiring members 73. Alternatively, a part of the process liquid coating 76 may remain on the surface of the insulating layer 71 as long as the remaining coating 76 does not impair the effect of the present invention.

In the drying substep S13, the flexible wiring circuit board 12 formed with the copper ion diffusion inhibiting film 77 is heat-dried. In the drying substep S13, it is preferable to completely remove moisture from the flexible wiring circuit board 12 because the remaining moisture may promote the copper ion migration. Note that the drying substep S13 is performed when necessary. The drying substep S13 may be omitted when the solvent used in the film forming step S1 has good volatility.

To reduce the oxidation of the copper wiring member 73, it is preferable to perform the heat-drying in the range of 70° C. to 120° C. (preferably 80° C. or more and 110° C. or less) for 15 seconds or more and 10 minutes or less (preferably, 30 seconds or more and 5 minutes or less). When the drying temperature is too low or the drying time is too short, the moisture may remain. When the drying temperature is too high or the drying time is too long, the copper oxide may be formed, which is not preferable. A device used for drying is not particularly limited. A known heating device, for example, a high temperature chamber or a heater may be used.

The wiring circuit board 55 of the discharge die 17 has a silicon substrate and copper wiring members arranged in a pattern on the silicon substrate. The outermost surface of each copper wiring member is plated with gold. However, the wiring circuit board 55 is not limited to the above example. Instead of the gold plating, the copper ion diffusion inhibiting film 77 composed of the azole compound may be formed on each copper or copper-alloy wiring member, in a manner similar to the flexible wiring circuit board 12.

In the aligning step S2, the first terminal section 32 of the wiring circuit board 55 of the discharge die 17 and the second terminal section 34 of the flexible wiring circuit board 12 are aligned to each other using a jig, such that first terminals 32a of the first terminal section 32 face respective corresponding second terminals 34a of the second terminal section 34.

In the heat-pressing step S3, the first and second terminal sections 32 and 34, aligned and put together, are pressed and heated. Thereby, the first and second terminal sections 32 and 34 are soldered together. Because each of the first and second terminal sections 32 and 34 is formed with a plated layer (not shown) of the same inorganic material, and the first and second terminal sections 32 and 34 are bonded together at a time, the bonding step is performed with a single step. In the heat-pressing step S3, the bonding using metal such as solder-melting or AuSn eutectic bonding may be used. Alternatively, a resin-based adhesive that allows electrical connection between the first and second terminal sections 32 and 34, for example, NCP (Non Conductive Paste), ACP (Anisotropic Conductive Paste), or ACF (Anisotropic Conductive Film) may be used. The NCP has both adhesive function and insulation function, and acts as an underfill material. To improve reliability of the electrical connection of an electrical connection portion of the first and second terminal sections 32 and 34, resin may be filled between the first and second terminal sections 32 and 34. The resin may be filled before or after the electrical connection between the first and second terminal sections 32 and 34 is established.

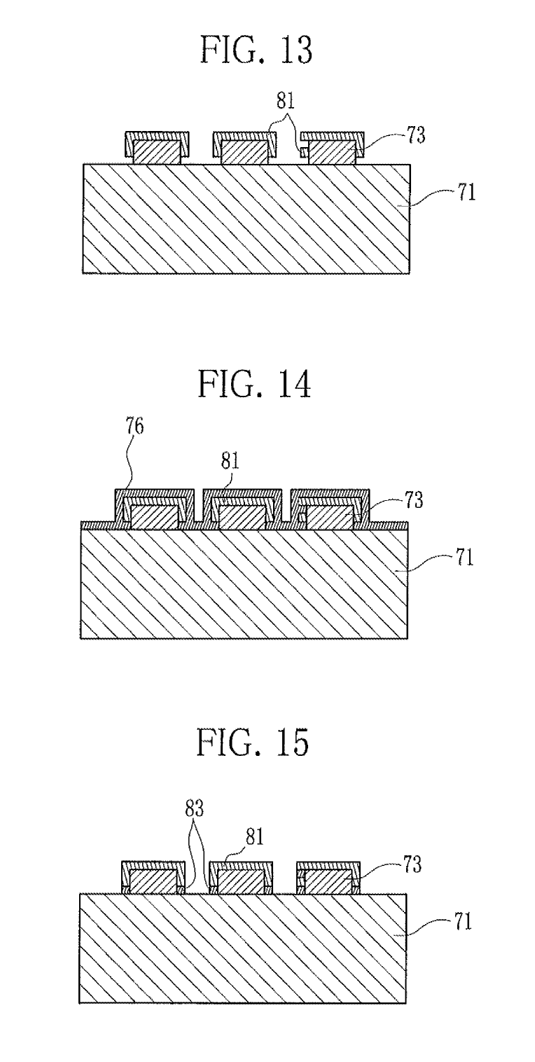

Note that in the above embodiment, the process liquid containing the azole compound is applied to the copper wiring member 73 of the flexible wiring circuit board 12 and then cleaned to form the copper ion diffusion inhibiting film 77 on the copper wiring member 73. Alternatively, as shown in FIGS. 13 to 15, a plating film 81 that is not made from copper may be formed on the copper wiring member 73 of the flexible wiring circuit board 12 (which may be referred to as the plating process). Then, similar to the first embodiment, the azole compound is applied to the plating film 81 to form a liquid coating 82 that forms a copper ion diffusion inhibiting film 83. In this case, the copper ion diffusion inhibiting film 83 is formed only on the exposed surface of the copper wiring member 73 on which the plating film 81 is not formed. Thereby, the copper ion migration is inhibited. In more detail, as shown in FIG. 13, even if the copper wiring member 73 is subjected to the plating process, a pinhole-shaped area is often left unplated or uncovered with the plating film 81 regardless of the distance to the insulating layer 71. The copper ion diffusion inhibiting film 83 is formed on the unplated area in a manner similar to the first embodiment. Although a step for forming the plating film 81 is performed additionally, the copper ion diffusion inhibiting film 83 inhibits the copper ion migration on the unplated area left after the plating process.

In the above embodiment, the flexible wiring circuit board 12 comes in contact with the process liquid containing the azole compound and then is cleaned to form the copper ion diffusion inhibiting films 77 on the surfaces of the copper wiring members 73 of the second terminal section 34. Alternatively or in addition, the copper ion diffusion inhibiting film(s) 77 may be formed on another set of copper wiring members arranged in a pattern, other than the copper wiring members 73 on the second terminal section 34, on the flexible wiring circuit board 12. The copper ion diffusion inhibiting film(s) 77 may be formed on another set of copper wiring members formed in a pattern, other than the copper wiring members on the first terminal section 32, on the discharge die 17.

In a third embodiment, the copper ion diffusion inhibiting film 77 is formed to cover every wiring pattern of the flexible wiring circuit board 12 (not shown). In this case, after the whole wiring patterns are formed using etching or the like, the flexible wiring circuit board 12 comes in contact with the process liquid containing the azole compound. Thereby, the copper ion diffusion inhibiting film 77 is formed to cover every wiring pattern. Then, the protective layer 75 is formed as necessary. Before or after the protective layer 75 is formed, necessary parts are attached to corresponding positions on the wiring pattern.

Next, evaluation on the effect of the inhibition of the ion migration in the flexible wiring circuit board 12 is described. As shown in FIG. 10, the flexible wiring circuit board 12 having the polyimide insulating layer 71 and the copper wiring members 73 formed on the insulating layer 71 was used for the evaluation. As for an arrangement pitch of the copper wiring members 73, a width of each of the copper wiring member 73 was 100 μm, and each space between the copper wiring members 73 was 100 μm. The copper wiring members 73 with no protective layer 75 were evaluated. The occurrence of the ion migration was compared between the flexible wiring circuit board 12 having the copper ion diffusion inhibiting films 77 as shown in FIG. 12 and the flexible wiring circuit board 12 with no copper ion diffusion inhibiting film 77 as shown in FIG. 10. To accelerate the occurrence of the ion migration, a drive voltage of DC 32V was applied. The flexible wiring circuit board 12 was left in a high temperature environment to relatively compare the occurrence of the ion migration, depending on a condition of the experiment. The occurrence of the ion migration was verified by measurement of a current value between the copper wiring members 73 and visual observation between the copper wiring members 73 using a microscope. To measure the current value between the copper wiring members 73, a circuit for applying the voltages 32V and GND (0V) alternately to the copper wiring members 73 is constituted. A resistance of, for example, 10 kΩ was directly placed in the circuit, and the voltage across the resistance was measured. Thereby, the current value was obtained. The current value increases when a short circuit occurs. By detecting the increase in the current value, the presence of the ion migration was judged. Note that a data logger (model: GL820 available from GRAPHTEC Corporation) was used as the measurement device.

The experiments were conducted under three conditions.

(1) The flexible wiring circuit board 12 was immersed in pure water.
(2) The flexible wiring circuit board 12 was immersed in diethylene glycol monobutyl ether-based solvent.
(3) The flexible wiring circuit board 12 was immersed in the diethylene glycol monobutyl ether-based solvent, kept at 85° C., in a state that the flexible wiring circuit board 12 was protected by fluorine-based resin sealant.

Under the condition (1), when the copper wiring members 73 were not provided with the copper ion diffusion inhibiting film 77, the ion migration occurred 9 minutes after the start of the immersion. On the other hand, when each copper wiring member 73 was provided with the copper ion diffusion inhibiting film 77, the ion migration occurred 12 minutes after the start of the immersion. Under the condition (2), when the copper wiring members 73 were not provided with the copper ion diffusion inhibiting film 77, the ion migration occurred 4 minutes after the start of the immersion. On the other hand, when each copper wiring member 73 was provided with the copper ion diffusion inhibiting film 77, the ion migration occurred 16 minutes after the start of the immersion. Under the condition (3), when each copper wiring member 73 was only provided with the fluorine-based resin sealant, the ion migration occurred 100 hours after the start of the immersion. On the other hand, when each copper wiring member 73 was provided with the copper ion diffusion inhibiting film 77 in addition to the fluorine-based resin sealant, the ion migration occurred 174 hours after the start of the immersion.

As described above, in all of the conditions (1) to (3), the copper wiring members 73 covered with the copper ion diffusion inhibiting films 77 delay the onset of the ion migration compared with those without the copper ion diffusion inhibiting film 77. Thus, the copper ion diffusion inhibiting film 77 is effective in inhibiting the copper ion diffusion.

Various changes and modifications are possible in the present invention and may be understood to be within the present invention.

What is claimed is:

1. An inkjet head comprising:
a wiring circuit board including an opening for supplying ink, an element for allowing the ink to be discharged, a wiring circuit for driving the element, and a first terminal section for inputting a drive signal for driving the element to the wiring circuit;
a flexible wiring circuit board including a second terminal section bonded and electrically connected to the first terminal section, the second terminal section inputting the drive signal to the first terminal section, the second terminal section having a first wiring member containing copper and a copper ion diffusion inhibiting film, the copper ion diffusion inhibiting film covering at least a part of the first wiring member and containing at least one of 1,2,3 triazole and 1,2,4 triazole.

2. The inkjet head of claim 1, further comprising a sealing section using resin, the resin being filled to cover a bonded portion of the first terminal section and the second terminal section from outside of the bonded portion.

3. The inkjet head of claim 1, wherein the first terminal section has a second wiring member containing the copper, and at least a part of the second wiring member is covered with the copper ion diffusion inhibiting film.

4. The inkjet head of claim 3, wherein at least one of the wiring circuit board and the flexible wiring circuit board has a third wiring member containing the copper, and at least a part of the third wiring member is covered with the copper ion diffusion inhibiting film.

5. The inkjet head of claim 4, wherein at least one of the first, second, and third wiring members is made of copper-alloy.

6. The inkjet head of claim 2, wherein the first terminal section has a second wiring member containing the copper, and at least apart of the second wiring member is covered with the copper ion diffusion inhibiting film.

7. The inkjet head of claim 6, wherein at least one of the wiring circuit board and the flexible wiring circuit board has a third wiring member containing the copper, and at least a part of the third wiring member is covered with the copper ion diffusion inhibiting film.

8. The inkjet head of claim 7, wherein at least one of the first, second, and third wiring members is made of copper-alloy.

9. The inkjet head of claim 1, wherein at least one of the wiring circuit board and the flexible wiring circuit board has a wiring member containing the copper, and at least a part of the wiring member is covered with the copper ion diffusion inhibiting film.

10. The inkjet head of claim 9, wherein at least one of the first wiring member and the wiring member is made of copper-alloy.

11. The inkjet head of claim 2, wherein at least one of the wiring circuit board and the flexible wiring circuit board has a wiring member containing the copper, and at least a part of the wiring member is covered with the copper ion diffusion inhibiting film.

12. The inkjet head of claim 11, wherein at least one of the first wiring member and the wiring member is made of copper-alloy.

13. The inkjet head of claim 1, wherein a part of the first wiring is covered with a plating film not containing the copper.

14. A method for producing an inkjet head, the inkjet head including a wiring circuit board having an opening for supplying ink, an element for allowing the ink to be discharged, a wiring circuit for driving the element, a first terminal section for inputting a drive signal for driving the element to the wiring circuit, the method comprising the steps of:
contacting a flexible wiring circuit board with a process liquid to form a process liquid coating on the flexible wiring circuit board, the flexible wiring circuit board including a second terminal section having a wiring member containing copper, the process liquid containing at least one of 1, 2, 3 triazole and 1, 2, 4 triazole;
washing away the process liquid coating with a solvent to remove the process liquid coating except for the process liquid coating on a surface of the wiring member so as to form a copper ion diffusion inhibiting film on the surface of the wiring member;
bonding and electrically connecting the second terminal section formed with the copper ion diffusion inhibiting film to the first terminal section; and
filling resin to cover a bonded portion of the first and second terminal sections from outside of the bonded portion.

15. The method of claim 14, further comprising the step of:
forming metal plating not containing the copper on the wiring member before contacting the flexible wiring circuit board with the process liquid.
